(19) United States
(12) Patent Application Publication
(10) Pub. No.: US 2022/0411932 A1
(43) Pub. Date: Dec. 29, 2022

(54) OXIDE FILM FORMING DEVICE

(71) Applicant: MEIDENSHA CORPORATION, Tokyo (JP)

(72) Inventor: Toshinori MIURA, Chiba-shi, Chiba (JP)

(73) Assignee: MEIDENSHA CORPORATION, Tokyo (JP)

(21) Appl. No.: 17/761,743

(22) PCT Filed: Jun. 16, 2020
(86) PCT No.: PCT/JP2020/023492

§ 371 Date: Mar. 18, 2022

(30) Foreign Application Priority Data
Sep. 20, 2019 (JP) 2019-172021

(51) Int. Cl. C23C 16/455; C23C 16/40

(52) U.S. Cl. CPC C23C 16/45563; C23C 16/402

(57) ABSTRACT

An oxide film forming device includes: a chamber in which a target workpiece is removably placed; a gas supply unit arranged at a position opposed to a film formation surface of the target workpiece placed in the chamber; and a gas discharge unit arranged to discharge a gas inside the chamber by suction to the outside of the chamber. The gas supply unit has a raw material gas supply nozzle, an ozone gas supply nozzle and an unsaturated hydrocarbon gas supply nozzle with supply ports thereof opposed to the film formation surface of the target workpiece at a predetermined distance away from the film formation surface. A raw material gas, an ozone gas and an unsaturated hydrocarbon gas supplied from the respective supply nozzles are mixed in a space between the supply ports and the film formation surface.

### FIELD OF THE INVENTION

The present invention relates to an oxide film forming device for forming an oxide film on a target workpiece by supplying to the target workpiece a raw material gas containing an element which constitutes the oxide film.

### BACKGROUND ART

It is common to form, on organic materials (as workpieces) for packaging applications, electronic components, flexible devices etc., inorganic films for surface protection and functionality addition. Further, the application of various flexible electronic devices in many fields is being studied where it is required to form inorganic films on e.g. organic films. For these reasons, there have been made studies on low-temperature film forming techniques capable of forming films on low heat-resistant workpieces such as organic films.

As film forming techniques, CVD (chemical vapor deposition) and PVD (physical vapor deposition) are exemplified. These film forming techniques have been used for the formation of various insulating films, conductive films etc. in the manufacturing processes of microelectronic devices. In general, CVD is superior to PVD in terms of film forming rate and coverage property.

A CVD method is known in which a film is formed on a target workpiece by reacting a raw material gas including a film forming element-containing compound (such as, for example, silane (a generic name for hydrogen silicate), TEOS (tetraethyl orthosillicate), TMA (trimethyl aluminium) or tungsten fluoride (WF₆)) with the addition of a reactive gas and depositing the thus-obtained reaction product onto the target workpiece.

The formation of films by such a CVD method is often performed at a high film forming temperature (e.g. under a high temperature condition exceeding several hundreds ° C.) in order to increase the reactivity between the respective gases and to improve the quality (such as insulating property and uniformity) of the films. A thermal CVD process and a plasma CVD process are known as examples of the high-temperature chemical vapor deposition method. For example, Patent Document 1 discloses a process of forming a SiO₂ film on a target workpiece by performing CVD with the use of an ozone gas (more specifically, a high concentration ozone gas and a TEOS gas) under a high temperature condition exceeding several hundreds ° C. by heating the target workpiece.

In the case of improving the film quality as in the high-temperature CVD method, however, it is difficult to decrease the film forming temperature. Thus, the kind of the target workpiece applicable is limited to those high in heat resistant temperature.

As a film forming technique capable of showing a relatively high reactivity between the respective gases even at a relatively low film forming temperature, there is known a method of forming an oxide film on a target workpiece by oxidizing a deposit, which has been formed in advance on the target workpiece, under a temperature condition of 100° C. or lower (e.g. successively oxidizing the deposit from the deposit surface in the thickness direction) as disclosed in e.g. Patent Document 2 (hereinafter also referred to as stepwise oxidation method). Furthermore, there is known an ashing technique of removing an organic substance under mom temperature conditions (see e.g. Patent Document 3) although it is different from the film forming techniques.

### PRIOR ART DOCUMENTS

### Patent Documents

Patent Document 1: Japanese Laid-Open Patent Publication No. 2007-109984
Patent Document 2: Japanese Laid-Open Patent Publication No. 2013-207005
Patent Document 3: Japanese Laid-Open Patent Publication No. 2008-294170

### SUMMARY OF THE INVENTION

In the stepwise oxidation method, it is feasible to improve the film quality of the oxidation film by homogenizing the deposit (e.g. uniformizing the thickness of the deposit).

In the case where a deposit is formed on a flexible target workpiece (such as an organic film having an uneven film formation surface), however, there conceivably occur a deviation in the thickness distribution of the deposit. When such a deposit is oxidized, there can arises a deviation in oxidation along the thickness direction of the deposition so that the thus-obtained oxidation film becomes nonuniform in film quality (e.g. shows a film quality deviation in the thickness direction).

The present invention has been made in view of the above-mentioned technical problems. It is an object of the present invention to provide a technique which contributes to a decrease of film forming temperature and an improvement of film quality.

As one aspect of the present invention to achieve the above object, there is provided an oxide film forming device for forming an oxide film on a film formation surface of a target workpiece, comprising: a chamber in which the target workpiece is placed; a gas supply unit arranged at a position opposed to the film formation surface of the target workpiece placed in the chamber; and a gas discharge unit arranged to discharge a gas inside the chamber by suction to the outside of the chamber and maintain the inside of the chamber in a reduced pressure state, wherein the gas supply unit comprises a tubular raw material gas supply nozzle for supplying a raw material gas into the chamber, a tubular ozone gas supply nozzle for supplying an ozone gas into the chamber and a tubular unsaturated hydrocarbon gas supply nozzle for supplying an unsaturated hydrocarbon gas into the chamber; the respective supply nozzles have supply ports opposed to and facing the film formation surface of the target workpiece at a predetermined distance away from the film formation surface, wherein the raw material gas, the ozone gas and the unsaturated hydrocarbon gas supplied from the respective supply nozzle are mixed in a space between the supply ports of the respective supply nozzles and the film formation surface; and wherein the raw material gas contains as its component element an element which constitutes the oxide film.

In this aspect, the opening axes of the supply ports of the respective supply nozzles may intersect at a position a predetermined distance away from the film formation surface.

The gas supply unit may have a triple tube structure in which the respective supply nozzles are disposed coaxially.

The distance from the supply ports of the respective supply nozzles to the film formation surface may stepwisely decrease toward an outer peripheral side of the triple tube structure.

The gas supply unit may have the ozone gas supply nozzle disposed on the center side of the triple tube structure and have the raw material gas supply nozzle disposed on the outer peripheral side of the triple tube structure.

Alternatively, the gas supply unit may have the raw material gas supply nozzle disposed on the center side of the triple tube structure and have the ozone gas supply nozzle disposed on the outer peripheral side of the triple tube structure.

The distance from the intersection of the opening axes of the supply ports of the respective supply nozzles to the film formation surface may be in the range of 5 mm to 5 cm.

The distance from the supply ports of the respective supply nozzles to the film formation surface may be in the range of 2 mm to 5 cm.

The above-mentioned aspect of the present invention contributes to a decrease of film forming temperature and an improvement of film quality.

### BRIEF DESCRIPTION OF DRAWINGS

FIG. 1 is a schematic cross-sectional view of an oxide film forming device 1 according to one embodiment of the present invention.

FIG. 2 is a cross-sectional view of the main part of a gas supply unit 3A of the oxide film forming device embodied as Embodiment Example 1.

FIG. 3 is a cross-sectional view of the main part of a gas supply unit 3B of the oxide film forming device embodied as Embodiment Example 2.

FIG. 4 is a cross-sectional view of the main part of a gas supply unit 3C of the oxide film forming device embodied as Embodiment Example 3.

### DESCRIPTION OF EMBODIMENTS

An oxide film forming device according to an exemplary embodiment of the present invention is totally different from devices using conventional high-temperature CVD method and stepwise oxidation method.

The oxide film forming device according to the present embodiment includes a gas supply unit arranged at a position opposed to a film formation surface of a target workpiece placed in a chamber, wherein the gas supply unit is provided with a tubular raw material gas supply nozzle for supplying a raw material gas (i.e. a gas containing as its component element a Si element or metal element which constitutes the oxide film), a tubular ozone gas supply nozzle for supplying an ozone gas and a tubular unsaturated hydrocarbon gas supply nozzle for supplying an unsaturated hydrocarbon gas.

In the present embodiment, the respective supply nozzles have supply ports opposed to and facing the film formation surface of the target workpiece at a predetermined distance away from the film formation surface such that the raw material gas, the ozone gas and the unsaturated hydrocarbon gas supplied from the respective supply nozzles are mixed in a space between the supply ports of the respective supply nozzles and the film formation surface (hereinafter also referred to as nozzle-to-workpiece space).

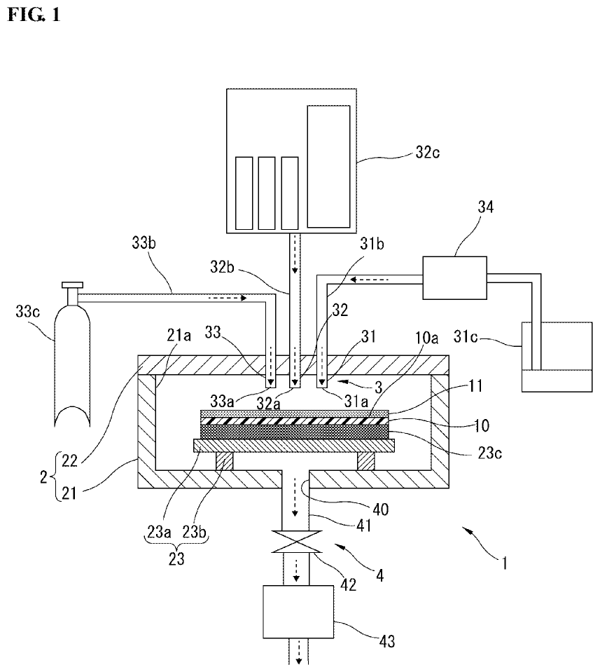

In this oxide film forming device, the ozone gas and the unsaturated hydrocarbon gas supplied into the chamber are mixed and reacted with each other to generate reactive species (OH radicals) within the nozzle-to-workpiece space. The generated reactive species is mixed and reacted with the raw material gas supplied to the chamber within the nozzle-to-workpiece space, thereby producing a reaction product. The reaction product gets deposited and adheres onto the film formation surface, whereby a desired oxide film (such as oxide film 11 shown in FIG. 1) is formed.

For example, the high-temperature CVD method may allow an increase of the reactivity between the respective gases even at a relatively low film forming temperature by the application of UV light irradiation, raises the possibility of change in the properties of the target workpiece (such as strength deterioration or transparency deterioration) due to UV light irradiation.

By contrast, the oxide film forming device according to the present embodiment enables heating of the reaction system in the nozzle-to-workpiece space by the heat of reaction of the ozone gas and the unsaturated hydrocarbon gas so as to increase the reactivity between the reactive species and the raw material gas.

In other words, the oxide film forming device according to the present embodiment attains a relatively high reactivity between the respective gases in the nozzle-to-workpiece space even without heating of the target workpiece (that is, even at a relatively low film forming temperature). Since the raw material gas supplied into the chamber is reacted with the reactive species within the nozzle-to-workpiece space before directly adhering to the film formation surface, it is possible to easily obtain the desired reaction product.

The raw material gas is thus prevented from adhering to the film formation surface (or the oxide film previously formed on the film formation surface) in an unreacted. state. This makes a contribution to the film quality improvement of the oxide film. Further, the target workpiece low in heat resistant temperature becomes easily applicable to the present embodiment as compared to the high-temperature CVD method.

The oxide film formed by depositing the reaction product on the film formation surface as mentioned above shows good step coverage property and easily obtains desired film quality, with less deviation in the thickness direction of the oxide film (as compared to that in e.g. the stepwise oxidation method), even when the target workpiece is in flexible form (such as organic film with uneven film surface).

The oxide film forming device according to the present embodiment can be provided in any configuration capable of mixing the raw material gas, the ozone gas and the unsaturated hydrocarbon gas supplied from the respective supply nozzles of the gas supply unit such that the reactive species generated by mixing and reaction of these gases (more specifically, the ozone gas and the unsaturated hydrocarbon gas) is mixed and reacted with the raw material gas, allowing the thus-obtained reaction product to be deposited onto the film formation surface and thereby forming the oxide film on the film formation surface. It is feasible to modify the design of the oxide film forming device by appropriately applying the common technical knowledge of various fields (such as film formation, chamber, ozone gas, unsaturated hydrocarbon and the like).

### Oxide Film Forming Device 1 as Example of Present Embodiment

FIG. 1 shows a general configuration of an oxide film forming device 1 as one example of the present embodiment. As shown in FIG. 1, the oxide film forming device 1 generally includes: a chamber 2 in which a target workpiece 10 is removably placed; a gas supply unit 3 arranged at a position opposed to a film formation surface 11 of the target workpiece 10 placed in the chamber 2; and a gas discharge unit 4 arranged to suck and discharge a gas inside the chamber 2 to the outside of the chamber 2.

The chamber 2 has a box-shaped chamber body 21 in which the workpiece 10 is placed; and an opening/closing lid 22 which seals an upper opening portion 21a of the chamber body 21 is sealed in such a manner that the opening portion 21a can be opened or closed freely. A support part 23 is provided on an inner bottom side of the casing body 21 so that the target workpiece 10 placed into the chamber 2 from the opening portion 21a is supported by the support part 23 with the film formation surface 10a directed and opposed to the opening/closing lid 22 (in FIG. 1, directed toward the upper side).

In the illustrated example of FIG. 1, the support part 23 has a flat plate-shaped support stage 23a on which the target workpiece 10 is placed and support columns 23b by which the support stage 23a is supported on the inner bottom side of the chamber body 21. A heating mechanism 23c is interposed between the support stage 23a and the target workpiece 10.

The gas supply unit 3 has a tubular raw material gas supply nozzle 31 for supplying a raw material gas into the chamber 2, a tubular ozone gas supply nozzle 32 for supplying an ozone gas into the chamber 2 and a tubular unsaturated hydrocarbon gas supply nozzle 33 for supplying an unsaturated hydrocarbon gas into the chamber 2 (hereinafter also generically referred to as supply nozzles 31 to 33). In the illustrated example of FIG. 1, the supply nozzles 31 to 33 are disposed to pass through the opening/closing lid 2 in a thickness direction of the opening/closing lid (e.g. an inside-outside direction of the chamber 2). Further, the supply nozzles 31 to 33 have, on one end sides (tip end sides) thereof, supply ports 31a to 33a opposed to and facing the film formation surface 10a at a predetermined distance away from the film formation surface 10a.

The supply nozzles 31 to 33 are connected at the other end sides thereof to a raw material gas source (such as a tank filled with a raw material gas) 31c, an ozone gas source (such as an ozone gas generator or a cylinder filled with a high concentration ozone gas) 32c and an unsaturated hydrocarbon gas source (such as a cylinder filled with an unsaturated hydrocarbon gas) 33c via pipes 31b to 33b, respectively. The pipe 31b may be equipped with a vaporizer 34 as shown in FIG. 1 so as to, when the raw material filled in the raw material gas source 31c is liquid at room temperature, vaporize the raw material into gas form by heating (e.g. to 70° C. or higher) with the vaporizer 34 and supply the resulting raw material gas into the chamber 2.

The gas discharge unit 4 has a discharge port 40 provided in the bottom side of the chamber 2. The gas discharge unit also has a discharge valve 42 and a discharge pump 43 (such as a dry pump resistant to ozone) each connected to a pipe 41 which is provided on a gas discharge side (downstream side) of the discharge port 44.

In the gas discharge unit 4, the gas inside the chamber 2 (such as the remaining unreacted amount of the raw material gas, the ozone gas and/or the unsaturated hydrocarbon gas supplied into the chamber 2) is discharged to the outside of the chamber 2 by suction force of the discharge pump 43 so as to control and maintain the inside of the chamber 2 in a reduced pressure state (i.e. a state where the pressure inside the chamber is lower than an atmospheric pressure).

The reduced pressure state of the chamber 2 is adjusted as appropriate, within the range that a desired oxide film 11 can be formed, during supply of the raw material gas, the ozone gas and the unsaturated hydrocarbon gas into the chamber 2. For example, the pressure inside the chamber 2 is reduced and adjusted to several thousands Pa or lower (e.g. about 1000 Pa or lower), preferably several hundreds Pa or lower (e.g. about 130 Pa), by appropriately controlling the opening of the discharge valve 4 and operating the discharge pump 43 as appropriate.

The components of the above-configured device 1 are not limited to those shown in FIG. 1. Furthermore, the target workpiece 10, the raw material gas, the ozone gas and the unsaturated hydrocarbon gas are applicable in various forms. The following are examples of the device components and gas materials.

<Support Part 23>

The support part 23 may be equipped with a moving mechanism (such as a moving state; not shown) capable of moving the support stage 23a to a desired position (e.g. moving the support stage in a direction along the film formation surface 10a (horizontal direction in FIG. 1)). The heating mechanism 23c disposed between the support stage 23a and the target workpiece 10 as shown in FIG. 1 is not an essential component and can be adopted as necessary (to obtain a relatively low film forming temperature (ranging from room temperature to 100° C.)). Examples of the heating mechanism include a thermocouple thermocouple, an infrared heater, a susceptor and the like.

<Gas Supply Unit 3>

The device 1 may be provided with a plurality of gas supply units 3. In this case, it is feasible to arrange a plurality of gas supply units 3 distributedly on the opening/closing lid 22 (e.g. arrange a plurality of gas supply units 3 distributedly in the direction along the film formation surface 10a (e.g. horizontal direction in FIG. 1) in such a manner that the respective supply nozzles 31 to 33 are directed and opposed to the film formation surface 10a at a predetermined distance away from the film formation surface 10a.

The supply nozzles 31 to 33 can be disposed in any appropriate arrangement configuration as long as the raw material gas, the ozone gas and the unsaturated hydrocarbon gas are supplied into the chamber 2 and mixed within the nozzle-to-workpiece space so as to allow mix and react the reactive species (generated by mixing and reaction of the ozone gas and the unsaturated hydrocarbon gas) with the raw material gas, allow the resulting reaction product to be deposited on the film formation surface 10a and thereby form the oxide film 11.

A distance from the supply ports of the respective supply nozzles to the film formation surface (hereinafter also referred to as nozzle-to-workpiece distance) is set as appropriate in view of the film quality and film forming rate of the oxide film 11 and the like.

When the nozzle-to-workpiece distance is too short, there is a possibility that the raw material gas in an unreacted state may adhere to the film formation surface 10a (or to the surface of the oxide film 11). This leads to an adverse influence on the film quality of the oxide film 11. When the nozzle-to-workpiece distance is too long, it would become difficult to attain a desired film forming rate (e.g. a film forming rate at which the oxide film 11 can be formed with a thickness of several nm or more per 1 minute).

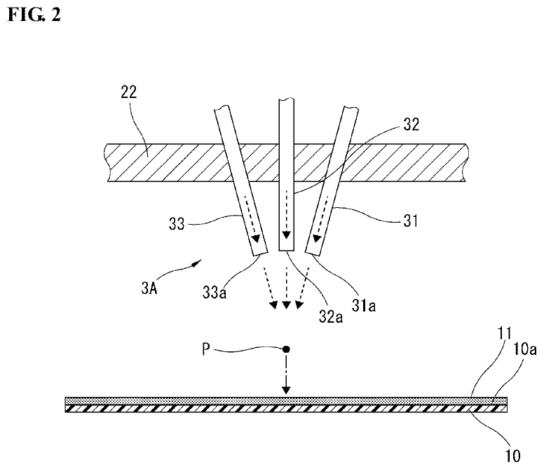

As a specific example of the arrangement configuration of the supply nozzles 31 to 33, it is feasible to arrange the supply nozzles 31 to 33 such that opening axes of the supply ports 31a to 33a of these supply nozzles intersect at a position a predetermined distance away from the film formation surface 10a as shown in FIG. 2. In this arrangement configuration, a distance from the intersection of the opening axes of the supply ports 31a to 33a (as designated by P in FIG. 2) to the film formation surface 10a (hereinafter also referred to as intersecting distance) may be set within the range of about several mm (e.g. 5 mm) to several cm (e.g. 5 cm).

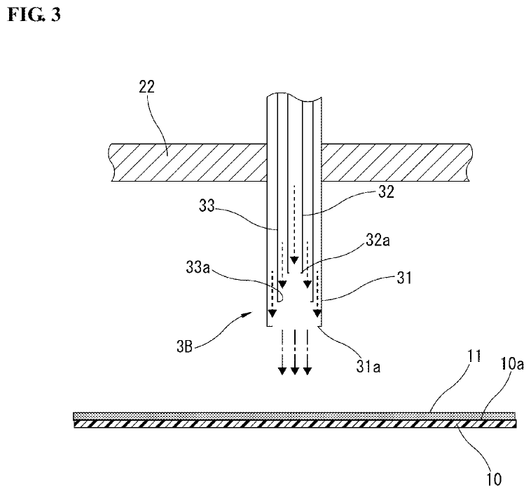

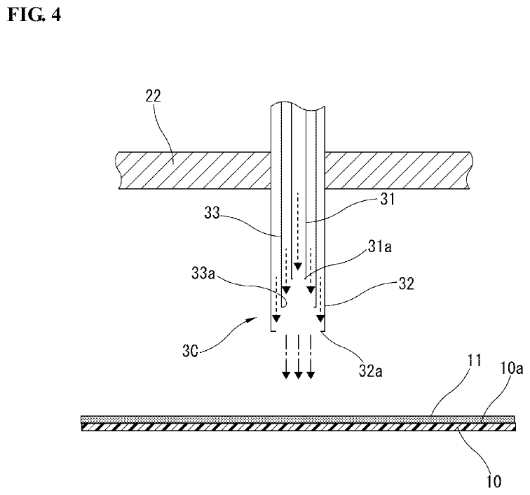

Alternatively, it is feasible to arrange the supply nozzles 31 to 33 coaxially in a triple tube structure (multiple tube structure) such that these supply nozzles extend vertically to the film formation surface as shown in FIGS. 3 and 4. In this arrangement configuration, the nozzle-to-workpiece distance may be set within the range of about several mm (e.g. 2 mm to 5 mm) to several cm (e.g. 3 cm to 5 cm).

<Target Workpiece 10>

As the target workpiece 10, a substrate, a film and the like are usable. The oxide film forming device 1 according to the present embodiment, which uses ozone and unsaturated hydrocarbon, enables formation of the oxide film 11 at a low temperature, whereby the oxide film 11 can be appropriately applied to not only a relatively high heat-resistant substrate such as Si substrate but also a substrate or film made of relatively low heat-resistant synthetic resin.

Examples of the synthetic resin usable as the material of the substrate or film include polyester resin, aramid resin, olefin resin, polypropylene, PPS (polyphenylene sulfide), PET (polyethylene terephthalate), PEN (polyethylene naphthalate) and the like. There can also be used PE (polyethylene), POM (polyoxymethylene; also called acetal resin), PEEK (polyether ether ketone), ABS resin (acrylonitrile-butadiene-styrene copolymerization synthetic resin), PA (polyamide), PFA (tetrafluoroethylene-perfluoroalkoxyethylene copolymer), (polyimide) PVD (polyvinyl dichloride) and the like.

<Ozone Gas>

It is preferable that the ozone concentration of the ozone gas in the ozone gas source 32c is as high as possible. For example, the ozone concentration (vol %) of the ozone gas is preferably in the range of 20 to 100 vol %, more preferably 80 to 100 vol %. The reason for this is that, as the ozone concentration is closer to 100 vol %, the reactive species (OH) generated from the ozone gas is supplied into the nozzle-to-workpiece space at a higher density. When the reactive species (OH) reaches the film formation surface 10a, the reactive species can be reacted with carbon (C) contained as an impurity in the film to remove the impurity carbon (C) in gaseous form.

Accordingly, the oxide film 11 is formed with less impurity by supplying a larger amount of the reactive species (OH) to the film formation surface 10a. In view of the tendency that the higher the ozone concentration of the ozone gas (i.e. the lower the oxygen concentration of the ozone gas), the longer the lifetime of atomic oxygen (O) generated by dissociation of the ozone, it is preferable to use the ozone gas of high concentration. As the ozone concentration is higher, the oxygen concentration is lower so that the atomic oxygen (O) is prevented from being deactivated by collision with the oxygen molecule. Further, the process pressure during the formation process of the oxide film 11 can be decreased with increase of the ozone concentration. It is thus preferable to use the high concentration ozone gas from the viewpoint of gas flow control and gas flow improvement as well as the above-mentioned atomic oxygen lifetime tendency.

There is no particular limitation on the flow rate of the ozone gas. The flow rate of the ozone gas is set as appropriate in view of the flow rates of the raw material gas and the unsaturated hydrocarbon gas etc. By way of example, the flow rate of the ozone gas may be set to 0.2 seem or higher, preferably 0.2 to 1000 seem. Herein, the unit “seem” refers to ccm (cm³/min) at 1 atm (1013 hPa) and 25° C.

Further, the flow rate (supply rate) of the ozone gas may be set equal to or higher than twice the flow rate (supply rate) of the unsaturated hydrocarbon gas. The reason for this is that, since the decomposition of the unsaturated hydrocarbon gas to OH group proceeds in a plurality of steps, a sufficient amount of OH group may not be obtained due to shortage of ozone molecule required for the reaction when the ozone gas and the unsaturated hydrocarbon gas are supplied at a ratio of ozone molecule:unsaturated hydrocarbon molecule=1:1. At the time when the unsaturated hydrocarbon gas and the raw material gas are supplied, the flow rate of the ozone gas may be set equal to or more than twice the total flow rate of the unsaturated hydrocarbon gas and the raw material gas so as to form the oxide film at a good film forming rate.

The high concentration ozone gas can be obtained by liquefying and separating ozone from an ozone-containing gas on the basis of a difference in vapor pressure, and then, gasifying the liquefied ozone. Specific examples of the ozone gas source 32 for generating the high concentration ozone gas include ozone gas generators disclosed in patent documents such as Japanese Laid-Open Patent Publication No. 2001-304756 and Japanese Laid-Open Patent Publication No. 2003-20209. These ozone gas generators disclosed as specific examples of the ozone gas source 32 are each configured to generate a high concentration ozone gas (ozone concentration 100 vol %) by isolating ozone through liquefaction separation based on a difference in vapor pressure between ozone and another gas (e.g. oxygen). The ozone gas source, particularly of the type having a plurality of chambers for liquefying and gasifying only ozone, enables continuous supply of the high concentration ozone gas by individual temperature control of the chambers. As one commercially available example of the ozone gas source 32c capable of generating the high concentration ozone, there is known Pure Ozone Generator (MPOG-HM1A1) manufactured by Meidensha Corporation.

<Raw Material Gas>

The raw material gas supplied from the raw material gas source 31c is a gas containing an element which constitutes the oxide film (such as lithium (Li), magnesium (Mg), silicon (Si), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), molybdenum (Mo), ruthenium (Ru), rhodium (Rh), indium (In), tin (Sn), tungsten (W), iridium (Ir), platinum (Pt) and lead (Pb); hereinafter referred to as metal or metal element). For example, the raw material gas can be a gas containing an organic silicon compound with a Si—O bond or Si—C bond or an organometallic compound with a metal-oxygen bond or metal-carbon bond, a gas containing a metal halide, an organometallic complex or a hydride of silicon or metal etc.

Specific examples of the raw material gas include those using silane (that is a generic name for hydrogen silicate), TEOS (tetraethyl orthosillicate), TMS (trimethoxysilane), TES (triethoxysilane), TMA (trimethyl aluminum), TEMAZ (tetrakis(ethylmethylamino)zirconium), tungsten fluoride (WF₆) and the like. There can also be used a gas of heterogeneous polynuclear complex containing a plurality of kinds of metal elements (as disclosed in e.g. Japanese Laid-Open Patent Publication No. 2016-210742), rather than containing one kind of metal element, is also usable.

There is no particular limitation on the flow rate of the raw material gas. The flow rate of the raw material gas is set as appropriate in view of the flow rates of the ozone gas and the unsaturated hydrocarbon gas etc. It is feasible to set the flow rate of the raw material gas to a level that the raw material gas supplied into the chamber 2 can be sufficiently reacted with the reactive species in the nozzle-to-workpiece space to form the desired reaction product before directly adhering to the film formation surface 10a. By way of example, the flow rate of the raw material gas may be set to 0.1 seem or higher, preferably 0.1 to 500 seem.

(Unsaturated Hydrocarbon Gas>

The unsaturated hydrocarbon gas supplied from the unsaturated hydrocarbon gas source 33c is a gas containing a hydrocarbon with a double bond (also called alkene) such as ethylene or a gas with a triple bond (also called alkyne) such as acetylene. In addition to ethylene and acetylene, a low-molecular-weight unsaturated hydrocarbon (e.g. an unsaturated hydrocarbon having a carbon number n of 4 or less) such as propylene, butylene etc. is also suitably usable as the unsaturated hydrocarbon.

There is no particular limitation on the flow rate of the unsaturated hydrocarbon gas. The flow rate of the unsaturated hydrocarbon gas is set as appropriate in view of the flow rates of the ozone gas and the raw material gas etc.

### Embodiment Example 1

FIG. 2 shows, in enlargement, a general configuration of the main part of the gas supply unit 3A according to Embodiment Example 1. Herein, the same components as those shown in FIG. 1 are designated by the same reference numerals; and detailed descriptions of those components will be omitted herefrom.

The supply nozzles 31 to 33 of the supply unit 3A are arranged such that the opening axes of the respective supply ports 31a to 33a (each of which extends in its gas supply direction) intersect at an intersection P which is located at a predetermined distance away from the film formation surface 10a.

In this gas supply unit 3A, the raw material gas, the ozone gas and the unsaturated hydrocarbon gas respectively supplied from the supply nozzles 31 to 33 into the chamber 2 are mixed at or around the intersection P (that is, mixed in the nozzle-to-workpiece space).

The formation of SiO₂ as the oxide film 11 was tested by applying the gas supply unit 3A to the device 1 and using a PET film as the target workpiece 10, a TEAS gas as the raw material gas, a high concentration ozone gas (with an ozone concentration close to 100 vol %) as the ozone gas and an ethylene gas as the unsaturated hydrocarbon gas. During the process of formation of the oxide film 11, the intersecting distance was set as appropriate within the range of 5 mm to 5 cm; the heating mechanism 23c was not operated (i.e. the target workpiece was not heated); and the inside of the chamber 2 was maintained in a reduced pressure state.

Consequently, the oxide film 11 was formed with a sufficient insulating property and uniformity on the film formation surface 10a of the target workpiece 10. It was confirmed that the oxide film 11 had a good refractive index (of about 1.45).

In the embodiment example of FIG. 2, the supply nozzle 32 is arranged to extend in a direction vertical to the film formation surface 10a; and the supply nozzles 31 and 33 are each inclined at an acute angle relative to the supply nozzle 32. The arrangement configuration of the supply nozzles 31 to 33 is however not limited to such an example. The same effects can be obtained as long as the opening axes of the respective supply ports 31a to 33a intersect at the intersection P as mentioned above. As one modification example, it is feasible to arrange all of the supply nozzles 31 to 33 in an inclined manner such that the opening axes of the supply ports 31a to 33 intersect at the intersection P.

### Embodiment Example 2

FIG. 3 shows, in enlargement, a general configuration of the main part of the gas supply unit 3B according to Embodiment Example 2. Herein, the same components as those shown in FIG. 1 and in Embodiment Example 1 are designated by the same reference numerals; and detailed descriptions of those components will be omitted herefrom.

The supply nozzles 31 to 33 of the gas supply unit 3B have horizontal cross-sectional shapes of different sizes, and form a triple tube structure by being coaxially arranged to extend in a direction vertical to the film formation surface 10a.

The gas supply unit 3B of FIG. 3 is configured such that the nozzle-to-workpiece distance stepwisely decreases toward the outer peripheral side of the triple tube structure. More specifically, the supply nozzle 32 is the smallest in horizontal cross-sectional shape (inner diameter) among the supply nozzles 31 to 33, and is located at the center side of the triple tube structure. The supply nozzle 33 is the second largest in horizontal cross-sectional shape among the supply nozzles 31 to 33, and is located so as to surround the supply nozzle 32 while maintaining a predetermined distance to the supply nozzle 32 in the horizontal cross-sectional direction. The supply nozzle 31 is the largest in horizontal cross-sectional shape (inner diameter) among the supply nozzles 31 to 33, and is located on the outer peripheral side of the triple tube structure so as to surround the supply nozzle 33 while maintaining a predetermined distance to the supply nozzle 33 in the horizontal cross-sectional direction. As a consequence, the distance from the supply nozzle 31 to the target workpiece is the shortest among the distances from the supply nozzles 31 to 33 to the target workpiece.

In this gas supply unit 3B, the raw material gas, the ozone gas and the unsaturated hydrocarbon gas respectively supplied from the supply nozzles 31 to 33 into the chamber 2 are mixed at or around the tip end side of the triple tube structure (that is, mixed in the nozzle-to-workpiece space). As compared with the case of the gas supply unit 3A, it is easy to adjust the position of the reaction system in the nozzle-to-workpiece space and is possible to improve the efficiencies of reactions of the raw material gas, the ozone gas and the unsaturated hydrocarbon gas (reactions associated with the reactive species and the reaction product).

By applying the gas supply unit 3B to the device 1, the formation of SiO₂ as the oxide film 11 was tested under the same conditions as in Embodiment Example 1. In the test, the nozzle-to-workpiece distances of the supply nozzles 31 to 33 were set appropriately as follows: the nozzle-to-workpiece distance of the supply nozzle 32 located on the center side of the triple tube structure was 5 cm or less; the nozzle-to-workpiece distance of the supply nozzle 31 located on the outer peripheral side of the triple tube structure was 5 mm or more; and the nozzle-to-workpiece distance of the supply nozzle 33 was about half of the sum of the nozzle-to-workpiece distances of the supply nozzles 31 and 32.

The oxide film 11 was consequently formed with a sufficient insulating property and uniformity on the film formation surface 10a of the target workpiece 10 as in the case of Embodiment Example 1. It was also confirmed that the oxide film 11 had a good refractive index (of about 1.45).

### Embodiment Example 3

FIG. 4 shows, in enlargement, a general configuration of the main part of the gas supply unit 3C according to Embodiment Example 3. Herein, the same components as those shown in FIG. 1 and in Embodiment Examples 1 and 2 are designated by the same reference numerals; and detailed descriptions of those components will be omitted herefrom.

As in the case of the gas supply unit 3B, the supply nozzles 31 to 33 of the gas supply unit 3C have horizontal cross-sectional shapes of different sizes, and form a triple tube structure by being coaxially arranged to extend in a direction vertical to the film formation surface 10a.

The gas supply unit 3C of FIG. 4 is also configured such that the nozzle-to-workpiece distance stepwisely decreases toward the outer peripheral side of the triple tube structure. More specifically, the supply nozzle 31 is the smallest in horizontal cross-sectional shape (inner diameter) among the supply nozzles 31 to 33, and is located at the center side of the triple tube structure. The supply nozzle 33 is the second largest in horizontal cross-sectional shape among the supply nozzles 31 to 33, and is located so as to surround the supply nozzle 32 while maintaining a predetermined distance to the supply nozzle 31 in the horizontal cross-sectional direction. The supply nozzle 32 is the largest in horizontal cross-sectional shape (inner diameter) among the supply nozzles 31 to 33, and is located on the outer peripheral side of the triple tube structure so as to surround the supply nozzle 33 while maintaining a predetermined distance to the supply nozzle 33 in the horizontal cross-sectional direction. As a consequence, the distance from the supply nozzle 32 to the target workpiece is the shortest among the distances from the supply nozzles 31 to 33 to the target workpiece.

In this gas supply unit 3C, the raw material gas, the ozone gas and the unsaturated hydrocarbon gas respectively supplied from the supply nozzles 31 to 33 into the chamber 2 are mixed at or around the tip end side of the triple tube structure (that is, mixed in the nozzle-to-workpiece space). As in the case of the gas supply unit 3B, it is easy to adjust the position of the reaction system in the nozzle-to-workpiece space and is possible to improve the efficiencies of reactions of the raw material gas, the ozone gas and the unsaturated hydrocarbon gas (reactions associated with the reactive species and the reaction product).

Furthermore, the raw material gas is supplied into the chamber 2 while being surrounded by the ozone gas and the unsaturated hydrocarbon gas. It is thus possible to suppress dispersion of the raw material gas to the outside of the nozzle-to-workpiece space, as compared with the case of the gas supply unit 3B, so that the raw material gas is easily prevented from adhering to the film formation surface 10a (or the surface of the oxide film 11) in an unreacted state.

By applying the gas supply unit 3C to the device 1, the formation of SiO₂ as the oxide film 11 was tested under the same conditions as in Embodiment Example 1. In the test, the nozzle-to-workpiece distances of the supply nozzles 31 to 33 were set appropriately as follows: the nozzle-to-workpiece distance of the supply nozzle 31 located on the center side of the triple tube structure was 5 cm or less; the nozzle-to-workpiece distance of the supply nozzle 32 located on the outer peripheral side of the triple tube structure was 2 mm or more; and the nozzle-to-workpiece distance of the supply nozzle 33 was about half of the sum of the nozzle-to-workpiece distances of the supply nozzles 31 and 32.

Consequently, the oxide film 11 was formed with a sufficient insulating property and uniformity on the film formation surface 10a of the target workpiece 10 as in the case of Embodiment Examples 1 and 2. It was also confirmed that the oxide film 11 had a good refractive index (of about 1.45).

Although the oxide film forming device according to the present invention has been described above by way of the specific embodiments, the oxide film forming device according to the present invention is not limited to those of the above-described specific embodiments. Various modifications and variations of the above-described embodiments are possible within the range that does not impair the features of the present invention. All such modifications and variations fall within the technical scope of the present invention.

In the case where the supply ports 31a to 33a of the supply nozzles 31 to 33 are each provided in a reduced diameter shape as shown in FIGS. 3 and 4, for example, the mixing of the gases (raw material gas, ozone gas and unsaturated hydrocarbon gas) supplied from the supply ports 31a to 33a can be promoted. However, the shapes of the supply nozzles are not limited to such a reduced diameter shape. It is feasible to change the design of the supply ports as appropriate (e.g. in such a manner that the diameters of the supply ports are respectively equal to the inner diameters of the supply nozzles 31 to 33).

1-8. (canceled)

9. An oxide film forming device for forming an oxide film on a film formation surface of a target workpiece, comprising:
a chamber in which the target workpiece is placed;
a gas supply unit arranged at a position opposed to the film formation surface of the target workpiece placed in the chamber; and
a gas discharge unit arranged to discharge a gas inside the chamber by suction to the outside of the chamber and maintain the inside of the chamber in a reduced pressure state,
wherein the gas supply unit comprises: a tubular raw material gas supply nozzle for supplying a raw material gas into the chamber; a tubular ozone gas supply nozzle for supplying an ozone gas into the chamber; and a tubular unsaturated hydrocarbon gas supply nozzle for supplying an unsaturated hydrocarbon gas into the chamber,
wherein the respective support nozzles are arranged distributedly in a direction along the film formation surface,
wherein supply ports of the respective supply nozzles are opposed to the film formation surface of the target workpiece at a predetermined distance away from the film formation surface,
wherein opening axes of the supply ports of the respective supply nozzles intersect at a position a predetermined distance away from the film formation surface,
wherein the raw material gas, the ozone gas and the unsaturated hydrocarbon gas supplied from the respective supply nozzles are mixed in a space between the supply ports of the respective supply nozzles and the film formation surface, and
wherein the raw material gas contains as a component element thereof a Si or metal element which constitutes the oxide film.

10. An oxide film forming device for forming an oxide film on a film formation surface of a target workpiece, comprising:
a chamber in which the target workpiece is placed;
a gas supply unit arranged at a position opposed to the film formation surface of the target workpiece placed in the chamber; and
a gas discharge unit arranged to discharge a gas inside the chamber by suction to the outside of the chamber and maintain the inside of the chamber in a reduced pressure state,
wherein the gas supply unit comprises: a tubular raw material gas supply nozzle for supplying a raw material gas into the chamber; a tubular ozone gas supply nozzle for supplying an ozone gas into the chamber; and a tubular unsaturated hydrocarbon gas supply nozzle for supplying an unsaturated hydrocarbon gas into the chamber,
wherein the gas supply unit has a triple tube structure in which the respective supply nozzles are coaxially arranged,
wherein supply ports of the respective supply nozzles each have a reduced diameter shape and are opposed to the film formation surface of the target workpiece at a predetermined distance away from the film formation surface,
wherein a distance between the supply ports of the respective supply nozzles and the film formation surface stepwisely decreases toward an outer peripheral side of the triple tube structure,
wherein the raw material gas, the ozone gas and the unsaturated hydrocarbon gas supplied from the respective supply nozzles are mixed in a space between the supply ports of the respective supply nozzles and the film formation surface, and
wherein the raw material gas contains as a component element thereof a Si or metal element which constitutes the oxide film.

11. The oxide film forming device according to claim 10, wherein the ozone gas supply nozzle is disposed on a center side of the triple tube structure, and the raw material gas supply nozzle is disposed on the outer peripheral side of the triple tube structure.

12. The oxide film forming device according to claim 10, wherein the raw material gas supply nozzle is disposed on a center side of the triple tube structure, and the ozone gas supply nozzle is disposed on the outer peripheral side of the triple tube structure.

13. The oxide film forming device according to claim 9, wherein a distance between an intersection of opening axes of the supply ports of the respective supply nozzles and the film formation surface is 5 mm to 5 cm.

14. The oxide film forming device according to claim 9, wherein a distance between the supply ports of the respective supply nozzles and the film formation surface is 2 mm to 5 cm.

15. The oxide film forming device according to claim 10, wherein a distance between the supply ports of the respective supply nozzles and the film formation surface is 2 mm to 5 cm.
